(19) United States
(12) Patent Application Publication
(10) Pub. No.: US 2011/0043161 A1
(43) Pub. Date: Feb. 24, 2011

(54) Electric wheels

(76) Inventors: Carlos Manuel Artieda, Centreville, VA (US); Luis Javier Artieda, SR., Lauderhill, FL (US)

Correspondence Address: Carlos M. Artieda, 14737 Jarnigan St., Centreville, VA, 20120, US

(21) Appl. No.: 12/583,321

(22) Filed: Aug. 19, 2009

(51) Int. Cl. H02J 7/00; H01L 41/00

(52) U.S. Cl. 320/107; 310/319; 180/65.21

(57) ABSTRACT

Our invention is focus on the fields of ecology and terrestrial transportation. The goal is to reduce the use of no-renewable fuels, as well as to reduce pollution consequences (the ecological impact).

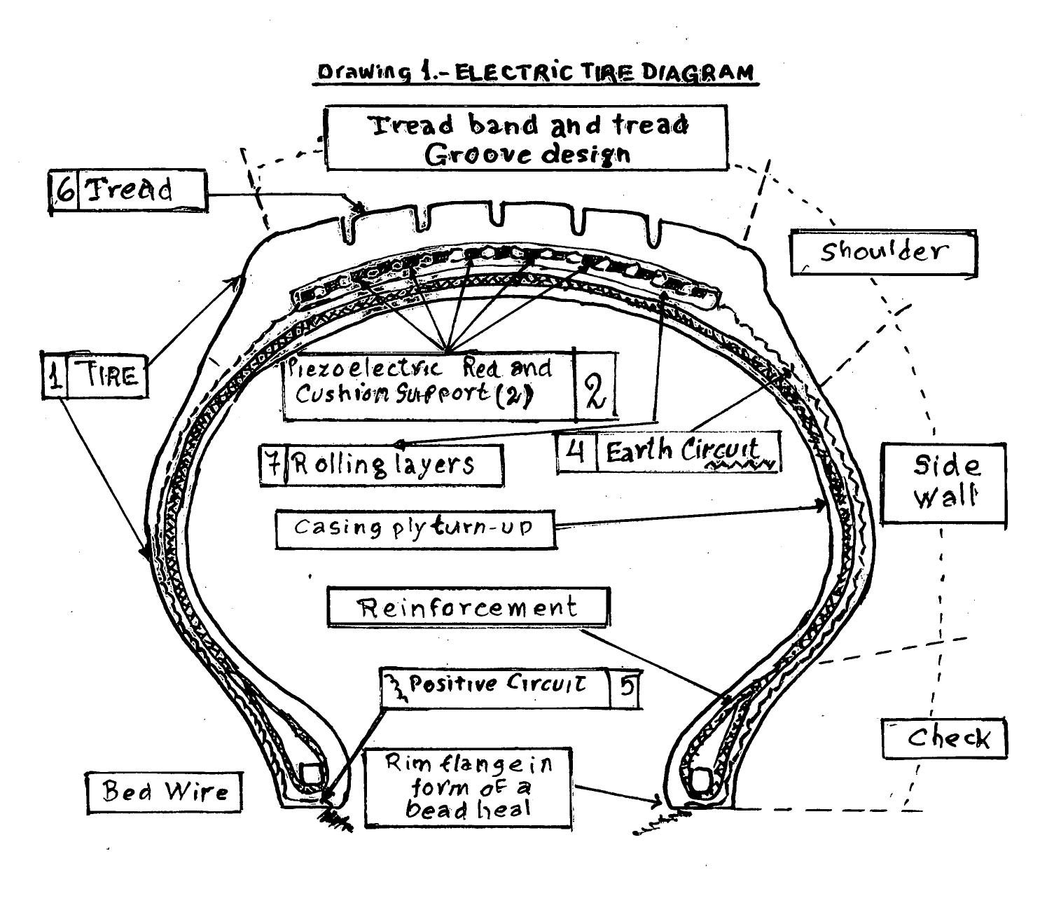

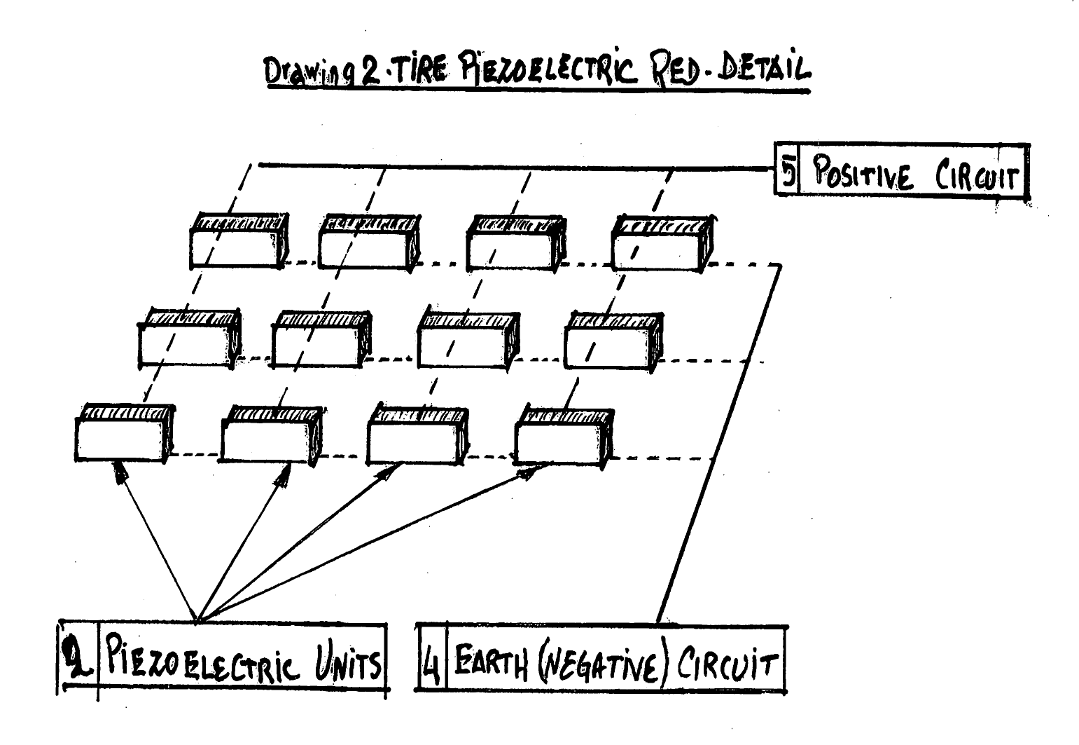

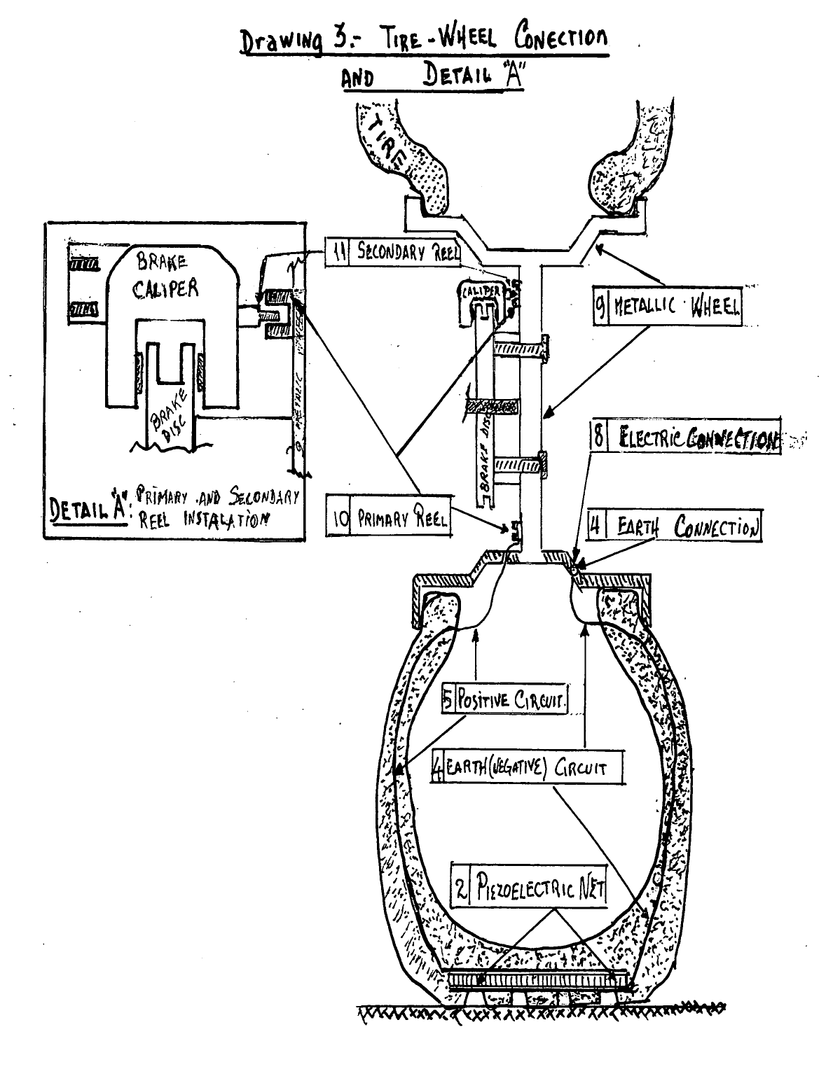

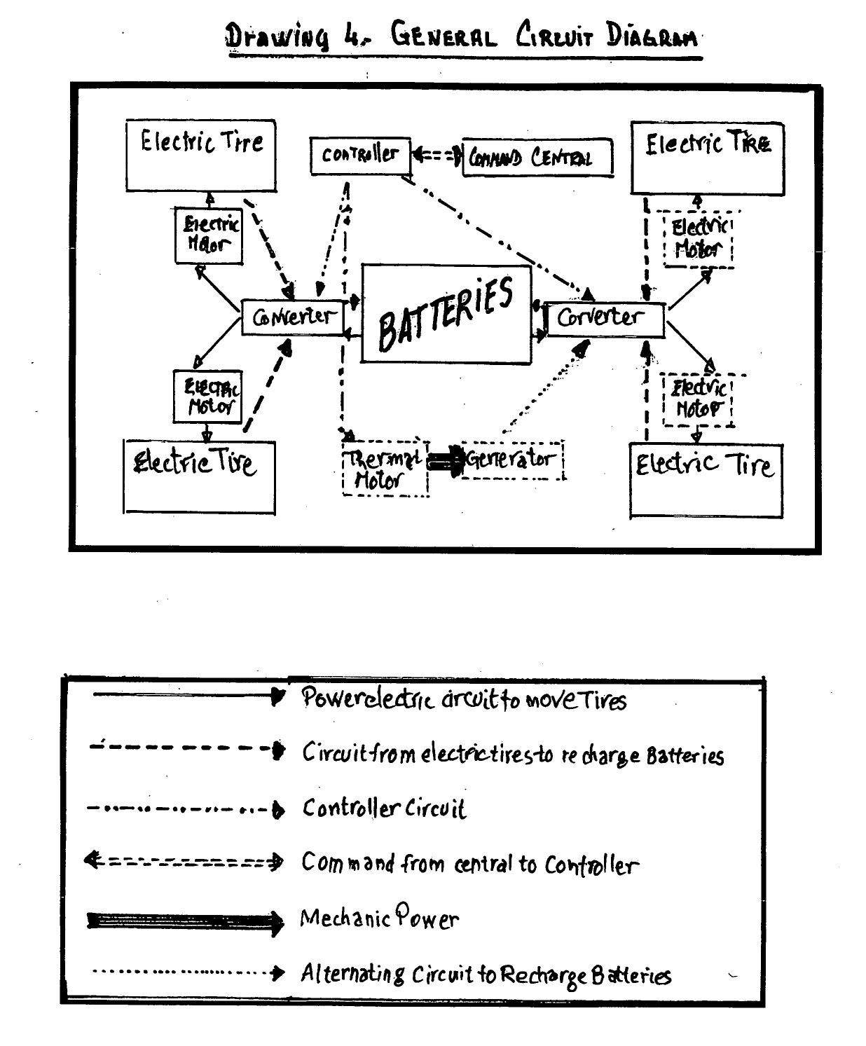

Our system will enhance currents systems by adding a component of energy generation that will:

Fossil fuel vehicles: Improve miles per gallon

Hybrid vehicles: improve miles per Gallon, Auto recharge battery

Electrical vehicles: Auto recharges battery

The world's roads are populated with motor vehicles that have tires filled with compress air/solid rubber. These tires rotate changing constantly the point of support. These points suffer vibrations and variance of pressure as result of supporting the car. Our system adds a piezoelectric material or other systems inside the tire. These piezoelectric elements, in combination with the gravity, will produce electricity. The electricity will be transported to the battery of the vehicle. This amounts to transforming gravity into electric energy.

### BACKGROUND OF THE INVENTION

Our ecology and the understanding of the limitation of resource are the genesis of this idea. The question we posted to our self was: How can we produce a limitless energy source and reduce the greenhouse gases?

We believe that the answer to those questions will move humans to a more sustainable development and reduce the negative effects of our current system. The health implications, ecology degradation, as well as the reduction of energy resources dependencies will improve every single country in the world.

Our global transportation is increasingly dependent on fossil fuel resources. The weight that vehicles needs to carried (body, engine) increase the consumption of fuel to generate the energy necessary for movement. This is an inefficient system because of the ratio of load versus vehicles weight.

These systems are contributors of carbon monoxide production affecting the human race health in different ways. Other unintended consequences of the present system could be the greenhouse gases. Human beings are paying a high price for the un-doubtable benefits of our terrestrial transport system.

The industry has tried to solve the problem introducing alternative systems like, electric motors, motors moved by bio-energy fuel, or gas, reduce vehicle weight, improve engine performance, and other combinations. Those efforts have improved the efficiency and they have reduced the emission of gases per unit, however the problem of the contamination continues to growth.

One area of study on the quest for efficiency that to our knowledge was not investigated was; how to use that weight (gravity) to improve efficiency.

In parallel, piezoelectric materials (solid materials that, when being pressed for a load, they produce electricity) is being developed as a source of moderate electricity production. The amount of electricity production is in direct relationship to the received load and its own physical dimension

This material has been improved through the years and today they are known for their stability and resistance.

### OUR INVENTION

A net of piezoelectric material will be installed in the rolling layer of all the tires of the vehicle. This material will be pressed and depressed by the weight (gravity) of the vehicle against the road. The rolling characteristics of the tire will make this a limitless source of energy. The production of electricity will increase or decrease based on the speed of the vehicle (revolution per minute of the wheels).

Our system will combine the limitless characteristics of this resources and the potential of collecting from each one of the tires of the vehicle, while it travels on the road, it will serve to constantly recharge the batteries of the vehicle.

In that form, our invention, will contribute to reduce air pollution and the emission of greenhouse gases.

### SUMMARY OF OUR INVENTION

Power generation is the act of collecting electrons at a useful electric potential.

Our invention utilizes the force of gravity to produce electricity that will be storage in vehicle batteries. This electricity will replace part of the petroleum used today in the propulsion and secondary systems of the vehicle (light, radio, starters, and power equipment), further reduce or replace fossil fuel engine in the hybrid vehicle, and recharging the battery in an electrical vehicle.

By using the weight of the combine product (vehicle+cargo) against the piezoelectric generator (PEG) to produce energy, we will reduce fuel consumption and increase hybrid vehicles performance.

This electrical current will be produced in the tire by the rotation of the wheel, creating points of pressure over the piezoelectric units located in the rolling layer of the tire. The electrical production can be calculated using the following formula:

Quantity of PEG (Piezoelectric Generator Unit) in a tire:

Q=[3.1416*D/d]*q

Where:

Q=Number of PEG in a tire

D=Diameter of the tire

d=longitudinal space between PEGs, plus one PEG's dimention

q=quantity of PEGs in a line

Electrical production of one tire, in one revolution.

Irt=Q*Ip

Where:

Id=Electrical production of one tire, in one revolution

Q=Number of PEG in a tire

Ip =Electrical production by PEG (Design characteristic)

The (PEG) will convert the pressure into electrical current, that current will be directed to a stabilization devise that will prepare it for storage into the battery.

The internal pressure of the air inside the tire produces a vector that pushes the (PEG) from the center of the wheel against the road (using the total weight of the car). The tire and PEG will face an opposite force that will be providing by the vector that starts on the road pushing up.

This opposite forces will create multiple, successive, and limitless moments of compression on the (PEG). In addition, this would be reproduced in all the tires of the vehicle.

The idea is to install a red of (PEG) connected in series-parallel in the inside of rolling layer of the tire. This will produce the exposure of the (PEG) to pressure and vibration that will produce the electricity.

This electric current will be appropriately transport to the batteries for storage. The amount of electricity, as we calculate before, will be directly related to the number of (PEG) elements installed, distance travel, and pressure.

This will reduce global consumption of fossil fuel, reduce contamination, increase vehicle efficiency, and improve hybrids systems.

### BRIEF DESCRIPTION OF THE DRAWINGS

Drawing 1. ELECTRIC TIRE DIAGRAM—This drawing Depict the position of the piezoelectric elements in relationship with the tread band. In addition, welded to both ends of the piezoelectric elements you will find the positive and negative cables that will carry the generated electricity. These positive and negative cables will be located inside the side-wall of the tire.

Drawing 2. TIRE PIEZOELECTRIC RED -DETAIL—This drawing shows the piezoelectric elements connected in red system. As can clearly see there are (orange) longitudinal cables connected to the inferior part of the PEGs, and (red) transversal cables connected to the upper part of the elements. The red wires are the positive connector cables of the tire's recharge circuit The orange wires are the earth or negative connector cables of the tire's recharge circuit

Drawing 3. TIRE-WHEEL Connection Detail—This drawing shows: The assembly of the wheel

Drawing 4. GENERAL CIRCUIT DIAGRAM—This drawing shows diverse circuits of a vehicle (power electric circuit to move the electric motors, batteries recharge's electric circuit, command and controller circuits, mechanic power circuit, and alternating recharge circuit).

### DETAILED DESCRIPTION

The “ELECTRIC WHEELS” System

The most constant, persistent, and inexhaustible natural resource is the gravitational force. Is present all around us affecting every element in earth that is physical located between the earth surfaces and the atmosphere day and night.

Our invention converts this force (the gravitational force) into electricity that will be accumulated in batteries to be used later by vehicles for movement and/or secondary systems. This invention combines several elements added to the wheel system of the vehicle.

It is important to remark that our invention, the “Electric Wheel”, uses the graveness as unique source of energy. When the vehicle is in movement the diverse systems of the invention will not offer additional resistance that it can increase fuel consumption to the vehicle power source's.

When the vehicle is moving, the production of electricity will happen al time. The amount of produced electricity shall be in direct proportion to the vehicle's characteristics (weight, speed, number of tires, etc) as well as the used piezoelectric characteristic's.

(Drawing 1) Electric Tire Diagram.—This Drawing illustrate an embodiment of the electric generation method of this invention. The wheel, pneumatic or solid (1), have mounted the red of Piezoelectric Elements (PEG) (2) electrically interconnected in series/parallel. That PEGs will react with the graveness producing electric current. That current will have compatible characteristics with the vehicle weight, the piezoelectric characteristics and the parts connection design.

(Drawing 2) Piezoelectric Red-Detail.—The PEGs (2) are connected to the red for their upper and lower side, so that all the Longitudinal Cables (4) are all connected to the same side of the PEG constituting the earth/negative part of the circuit. In the other side are connected the Transversal Positive Cables (5) constituting the positive part of the circuit.

The PEGs (2) will be located under Tread (6) and inside of the Rolling Layers (7). The point of greatest pressure, moment by moment, it is the one that is directly in contact with the pavement, this part of the Tread (6) transmit this pressure change to the Rolling Layers (7). The Rolling Layers (7) absorb that change of pressure and they transmit them to the red of PEGs (2). In the PEGs (2) it is generated the electric current.

The generated electric current will be collected, rectified and directed to the batteries of the vehicle.

(Drawing 3) Tire-Wheel Connection Detail.—The Longitudinal Cables (4) are interconnected by sectors for to settle down the electric characteristics of voltage and amperage required by design. The Positive cables (5) cross the Metallic Wheel (9) (without causing loss of pneumatic pressure) to be connected to the Primary Reel (10).

(Drawing 3-Detail A) Reel's Assembly.—The Metallic Wheel (9) has been modified to incorporate the Primary Reel (10) that will be fed by the electric current that arrives from the red of PEGs. The positive arrives through the cables (5), the negative arrives through the Metallic Wheel (9), on which is solidly mounted the Primary Reel (10). This Primary Reel (10) creates an electromagnetic field.

The Secondary Reel (11), that it is mounted in the Brake Caliper (12) and receives the electric impulse from the electromagnetic field created by the Primary Reel (10), transforms again that impulse in electric current that will be used to recharge the vehicle battery.

Considering some characteristics of the piezoelectric material the Reels, Primary (10) and Secondary (11), could be replaced by piezoelectric of appropriate characteristics.

(Drawing 4) General Circuit Drawing.—The generated electric current is transferred to the vehicle's battery through an appropriate circuit, and it is stored to be used by the vehicle.

What we claim is:

1. A method of to use the graveness to produce electric energy to recharge the vehicle battery, comprising the steps of:
Using a modified version of the normal vehicle tires where we will locate piezoelectric elements, electric circuits, and a primary and secondary reel, electric regulator, vehicle battery.
Using the said graveness force that produces the instantaneous increment of pressure, that it happen during the said wheel's rotation. This happens in the point of tire's contact with the pavement
Producing an electric sign when the said piezoelectric elements, incorporated in the said rolling layer, are subjected to the said increase of pressure
Creating a continuous electric current, produced by the said wheel rotation that it create multiple and successive points of high pressure.
Conducting the said electric current to the said primary reel to create an electromagnetic camp
Inducting that said electric current in a secondary reel located in the vehicle's body, with compatible characteristics to the primary reel.
Transmitting the said electric current to an electric regulator, that regulator has compatible characteristics with the battery.
Recharging the vehicle battery with the said electric current that was regulated in the said electric regulator

2. An electric wheel-generator. This is a modified version of a normal pneumatic vehicle tire in which, during the manufacturing process, a reticular net of piezoelectric elements will be added in the rolling layer of all the tires. The piezoelectric elements are electrically interconnected with longitudinal wires, and transverse cables.
During the rotation of the wheel an instantaneous increase of pressure, it takes place in the point of contact of the tire with the pavement. This differential of pressure makes that the PEGs compressed by that force it will produced an electric sign.
The wheel rotation will create multiple and successive points of pressure increase. The PEG will convert the pressure into electrical current that will be directed to a ring form reel mounted in the metallic part of the wheel. This reel it will create an electric camp
That camp will induce an electric current in the secondary reel mounted in the stationary part of the brake.
The created electric current will be transfer through a stabilizer device, that device regulates the current for its storage in the vehicle battery.

3. An electric wheel-generator as recited in claim 2, wherein the tires are made of solid rubber.

4. An electric wheel-generator as recited in claim 2, wherein piezoelectric materials will be added from manufacture in the rolling layer of all the tires of the vehicle.

5. An electric wheel-generator as recited in claim 2, wherein we will use piezoelectric generators (PEG) to install in the rolling layer of any “any kind” of vehicle tires modifying it with the goal of electric/power generation.

6. The use of the piezoelectric generator (PEG) to install them in the rolling layer on “vehicle tires of any kind” modifying it with the goal of electric/power generation.

7. The system of transferring and transmitting the electricity, produced in the electric wheel-generator, into a stabilization devise that will prepare it for storage into the battery.

8. An electric wheel-generator as recited in claim 2, wherein the vehicle tires are modified with any kind of element to transform it into an electric generator.

9. The use of any kind of element to transform vehicle wheels, of any kind, into electric generators.
